(19) United States
(12) Patent Application Publication
(10) Pub. No.: US 2024/0377719 A1
(43) Pub. Date: Nov. 14, 2024

(54) SUBSTRATE WITH MULTILAYER REFLECTIVE FILM REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventors: Teiichiro UMEZAWA, Tokyo (JP); Yohei IKEBE, Tokyo (JP)

(73) Assignee: HOYA CORPORATION, Tokyo (JP)

(21) Appl. No.: 18/692,007

(22) PCT Filed: Sep. 22, 2022
(86) PCT No.: PCT/JP2022/035292

§ 371 Date: Mar. 14, 2024

(30) Foreign Application Priority Data
Sep. 30, 2021 (JP) 2021-160857

(51) Int. Cl. G03F 1/24; G03F 1/48; G03F 1/54

(52) U.S. Cl. CPC G03F 1/24; G03F 1/48; G03F 1/54

(57) ABSTRACT

Provided is a substrate with a multilayer reflective film comprising a multilayer reflective film having a shallow effective reflective surface and capable of suppressing a phenomenon that atoms to be a material are diffused between a low refractive index layer and a high refractive index layer.

A substrate with a multilayer reflective film comprises a substrate and a multilayer reflective film formed on the substrate, in which the multilayer reflective film comprises a multilayer film in which a low refractive index layer and a high refractive index layer comprising silicon (Si) are alternately layered, the multilayer reflective film further comprises at least one intermediate layer disposed between the low refractive index layer and the high refractive index layer, the multilayer reflective film comprises at least one additive element selected from nitrogen (N), carbon (C), and oxygen (O), and the content of the additive element in the multilayer reflective film is 40 atom % or less.

### CROSS-REFERENCE TO RELATED APPLICATIONS

The present application is the National Stage of International Application No. PCT/JP2022/035292, filed on Sep. 22, 2022, which claims priority to Japanese Patent Application No. 2021-160857, filed on Sep. 30, 2021, and the contents of which is incorporated by reference.

### TECHNICAL FIELD

The present disclosure relates to a substrate with a multilayer reflective film, a reflective mask blank, a reflective mask, and a method for manufacturing a semiconductor device.

### BACKGROUND ART

With a further demand for higher density and higher accuracy of a VLSI device in recent years, extreme ultraviolet (hereinafter referred to as “EUV”) lithography, which is an exposure technique using EUV light, has been proposed.

A reflective mask includes a multilayer reflective film for reflecting exposure light formed on a substrate, and an absorber pattern which is a patterned absorber film formed on the multilayer reflective film for absorbing exposure light. A light image reflected by the multilayer reflective film is transferred onto a semiconductor substrate (transferred object) such as a silicon wafer through a reflective optical system.

As an example of a reflective mask blank for manufacturing a reflective mask, Patent Document 1 describes an EUV blank mask including a substrate, a reflective film layered on the substrate, and an absorption film layered on the reflective film. Patent Document 1 describes that the reflective film has a structure in which a pair including a first layer made of Ru or made of a Ru compound in which one or more elements of Mo, Nb, and Zr are added to Ru and a second layer made of Si is layered a plurality of times.

Patent Document 2 describes a multilayer reflective mirror for soft X-rays and vacuum ultraviolet rays, having a multilayer thin film structure including alternating layers of two types of main materials A and B having different refractive indices. Patent Document 2 describes that at least one sub-material thin film having a function of reducing roughness of a stacking interface is layered between the A layer and the B layer and/or between the B layer and the A layer to form a periodic structure. Patent Document 2 describes that a low refractive index layer is generally formed of a high melting point metal material such as tungsten or molybdenum or a compound containing the high melting point metal material as a main component, and a high refractive index layer is generally formed of a light element such as carbon, silicon, boron, or beryllium or a compound containing the light element as a main component. Furthermore, Patent Document 2 describes that examples of the sub-material include a conductor of a light element having an atomic number of 13 or less, such as carbon C, boron B, beryllium Be, silicon carbide SiC, silicon nitride Si₃N₄, silicon oxide SiO₂, boron nitride BN, boron carbide B₄C, or aluminum nitride AlN, and compounds thereof.

Patent Document 3 describes a multilayer film spectral reflective mirror in which a compound intermediate layer containing Si and C is used between a heavy element layer and a light element layer of a multilayer film spectral element having a Bragg diffraction effect. In addition, Patent Document 3 describes that the multilayer film is prepared using Mo, Ru, Rh, and Re as the heavy element layer, Si as the light element layer, and Si₁₀₀₋ₓCₓ as the intermediate layer.

Patent Document 4 describes a multilayer film X-ray reflective mirror in which a plurality of substance layers are periodically layered. Patent Document 4 describes that an intermediate layer is formed between the substance layers, and a substance having a higher melting point than that of at least one of the substance layers is used as the intermediate layer. In addition, Patent Document 4 describes that a Mo/Si multilayer film is prepared using Mo as a heavy element layer, and Si as a light element layer.

Non Patent Document 1 describes that a B₄C interlayer film (interlayer) is used for a Mo/Si multilayer reflector. In addition, Non Patent Document 1 describes that a Ru/Si multilayer reflective film is used as a multilayer reflector.

### PRIOR ART DOCUMENTS

### Patent Documents

Patent Document 1: JP 2021-110953 A
Patent Document 2: JP H02-242201 A
Patent Document 3: JP H05-203798 A
Patent Document 4: JP H09-230098 A

### Non Patent Document

Non Patent Document 1: Overt Wood et al. “Improved Ru/Si multilayer reflective coatings for advanced extreme-ultraviolet lithography photomasks”. Proc. SPIE 9776, Extreme Ultraviolet (EUV) Lithography VII, 977619 (18 Mar. 2016)

### DISCLOSURE OF INVENTION

The above-described EUV lithography is an exposure technique using extreme ultraviolet light (EUV light). The EUV light refers to light in a wavelength band of a soft X-ray region or a vacuum ultraviolet region, and is specifically light having a wavelength of about 0.2 to 100 nm. In the EUV lithography, EUV light having a wavelength of 13 to 14 nm (for example, a wavelength of 13.5 nm) can be used.

In the EUV lithography, a reflective mask having an absorber pattern is used. EUV light with which the reflective mask is irradiated is absorbed in a portion where the absorber pattern is present, and is reflected in a portion where the absorber pattern is not present. A multilayer reflective film is exposed in the portion where the absorber pattern is not present. The exposed multilayer reflective film reflects the EUV light. In the EUV lithography, a light image reflected by the multilayer reflective film (a portion where the absorber pattern is not present) is transferred onto a semiconductor substrate (transferred object) such as a silicon wafer through a reflective optical system.

As the multilayer reflective film, a multilayer film in which elements having different refractive indices are periodically layered is used. For example, as a multilayer reflective film with respect to EUV light having a wavelength of 13 nm to 14 nm (for example, a wavelength of 13.5 nm), a Mo/Si periodic layered film in which a Mo film having a low refractive index and a Si film having a high refractive index are alternately layered for 40 to 60 periods is used.

In order to achieve high density and high accuracy of a semiconductor device using the reflective mask, a reflection region (surface of a multilayer reflective film) in the reflective mask needs to have a high reflectance with respect to EUV light that is exposure light.

As a node (minimum line width) to be transferred onto a transferred object such as a semiconductor substrate is narrower, an influence of a 3D effect on transfer characteristics is larger. In order to suppress the 3D effect, it is effective to reduce the film thickness of the absorber pattern. However, in the EUV lithography using reflection exposure, it is not sufficient to reduce the thickness of the absorber film for forming the absorber pattern. Therefore, it is also necessary to control a reflective surface on which EUV light is reflected. As the control of the reflective surface, specifically, it is necessary to control the reflective surface such that EUV light reflected from the multilayer reflective film does not spread by bringing an effective reflective surface of the multilayer reflective film as close as possible to a surface. In the present specification, an effective reflective surface relatively close to the surface of the multilayer reflective film may be referred to as a “shallow effective reflective surface”. By presence of the shallow effective reflective surface in the multilayer reflective film, the 3D effect can be suppressed, and the number of layered multilayer reflective films can be reduced.

In order to bring the effective reflective surface of the multilayer reflective film as close as possible to the surface, it is necessary to select a material of the multilayer reflective film so as to increase a reflectance with respect to EUV light. The multilayer reflective film has a stack of a low refractive index layer and a high refractive index layer, and thus reflects EUV light. When the material of the multilayer reflective film is selected so as to increase the reflectance with respect to EUV light, depending on the material, a phenomenon that atoms to be the material are diffused between the low refractive index layer and the high refractive index layer may occur. When such a diffusion phenomenon occurs, the reflectance of the multilayer reflective film decreases.

Therefore, an aspect of the present disclosure is to provide a substrate with a multilayer reflective film, a reflective mask blank, and a reflective mask, including a multilayer reflective film having a shallow effective reflective surface and capable of suppressing a phenomenon that atoms to be a material are diffused between a low refractive index layer and a high refractive index layer. Another aspect of the present disclosure is to provide a method for manufacturing a semiconductor device using the reflective mask.

In order to solve the above problems, the present disclosure has the following configurations.

### (Configuration 1)

Configuration 1 of the present disclosure is a substrate with a multilayer reflective film comprising a substrate and a multilayer reflective film formed on the substrate, in which
the multilayer reflective film comprises a multilayer film in which a low refractive index layer and a high refractive index layer comprising silicon (Si) are alternately layered,
the multilayer reflective film further comprises at least one intermediate layer disposed between the low refractive index layer and the high refractive index layer,
the multilayer reflective film comprises at least one additive element selected from nitrogen (N), carbon (C), and oxygen (O), and
the content of the additive element in the multilayer reflective film is 40 atom % or less.

### (Configuration 2)

Configuration 2 of the present disclosure is the substrate with a multilayer reflective film according to configuration 1, in which the content of the additive element is 1 atom % or more.

### (Configuration 3)

Configuration 3 of the present disclosure is the substrate with a multilayer reflective film of configuration 1 or 2, in which the intermediate layer comprises at least one selected from SiN, SiO, SiC, SiON, SiCN, SiOC, and SiOCN.

### (Configuration 4)

Configuration 4 of the present disclosure is the substrate with a multilayer reflective film according to any one of configurations 1 to 3, in which the low refractive index layer comprises ruthenium (Ru).

### (Configuration 5)

Configuration 5 of the present disclosure is the substrate with a multilayer reflective film according to any one of configurations 1 to 4, in which
the low refractive index layer comprises ruthenium (Ru), and
when a stack of the one low refractive index layer and the one high refractive index layer is taken as one period, the stack is layered for less than 40 periods.

### (Configuration 6)

Configuration 6 of the present disclosure is the substrate with a multilayer reflective film according to any one of configurations 1 to 5, further comprising a protective film on the multilayer reflective film.

### (Configuration 7)

Configuration 7 of the present disclosure is the substrate with a multilayer reflective film according to configuration 6, in which the protective film comprises a SiN material layer comprising silicon (Si) and nitrogen (N) or a SiC material layer comprising silicon (Si) and carbon (C) on a side in contact with the multilayer reflective film.

### (Configuration 8)

Configuration 8 of the present disclosure is a reflective mask blank comprising an absorber film on the protective film of the substrate with a multilayer reflective film according to configuration 6 or 7.

### (Configuration 9)

Configuration 9 of the present disclosure is a reflective mask blank comprising an absorber film on the multilayer reflective film of the substrate with a multilayer reflective film according to any one of configurations 1 to 5.

### (Configuration 10)

Configuration 10 of the present disclosure is a reflective mask comprising an absorber pattern obtained by patterning the absorber film of the reflective mask blank according to configuration 8 or 9.

### (Configuration 11)

Configuration 11 of the present disclosure is a method for manufacturing a semiconductor device, comprising performing a lithography process with an exposure apparatus using the reflective mask according to configuration 10 to form a transfer pattern on a transferred object.

The present disclosure can provide a substrate with a multilayer reflective film, a reflective mask blank, and a reflective mask, including a multilayer reflective film having a shallow effective reflective surface and capable of suppressing a phenomenon that atoms to be a material are diffused between a low refractive index layer and a high refractive index layer. In addition, the present disclosure can provide a method for manufacturing a semiconductor device using the reflective mask.

### BRIEF DESCRIPTION OF DRAWINGS

FIG. 1 is a schematic cross-sectional view illustrating an example of a substrate with a multilayer reflective film of the present embodiment.

FIG. 2 is a schematic cross-sectional view illustrating another example of the substrate with a multilayer reflective film of the present embodiment.

FIG. 3 is a schematic cross-sectional view illustrating an example of a reflective mask blank of the present embodiment.

FIG. 4 is a schematic cross-sectional view illustrating another example of the reflective mask blank of the present embodiment.

FIG. 5 is a schematic cross-sectional view illustrating still another example of the reflective mask blank of the present embodiment.

FIGS. 6A to 6D are schematic cross-sectional views illustrating an example of a method for manufacturing a reflective mask of the present embodiment.

FIG. 7 is a schematic cross-sectional view illustrating a first aspect of a multilayer reflective film of the substrate with a multilayer reflective film of the present embodiment.

FIG. 8 is a schematic cross-sectional view illustrating a second aspect of the multilayer reflective film of the substrate with a multilayer reflective film of the present embodiment.

FIG. 9 is a schematic cross-sectional view illustrating a third aspect of the multilayer reflective film of the substrate with a multilayer reflective film of the present embodiment.

FIG. 10 is a schematic cross-sectional view illustrating a fourth aspect of the multilayer reflective film of the substrate with a multilayer reflective film of the present embodiment.

FIG. 11 is a schematic cross-sectional view illustrating a fifth aspect of the multilayer reflective film of the substrate with a multilayer reflective film of the present embodiment.

FIG. 12 is a schematic cross-sectional view illustrating a sixth aspect of the multilayer reflective film of the substrate with a multilayer reflective film of the present embodiment.

FIG. 13 is a schematic diagram illustrating an example of an EUV exposure apparatus.

### DESCRIPTION OF EMBODIMENTS

Hereinafter, an embodiment of the present disclosure will be specifically described with reference to the drawings. Note that the following embodiment is a mode for specifically describing the present disclosure and does not limit the present disclosure within the scope thereof.

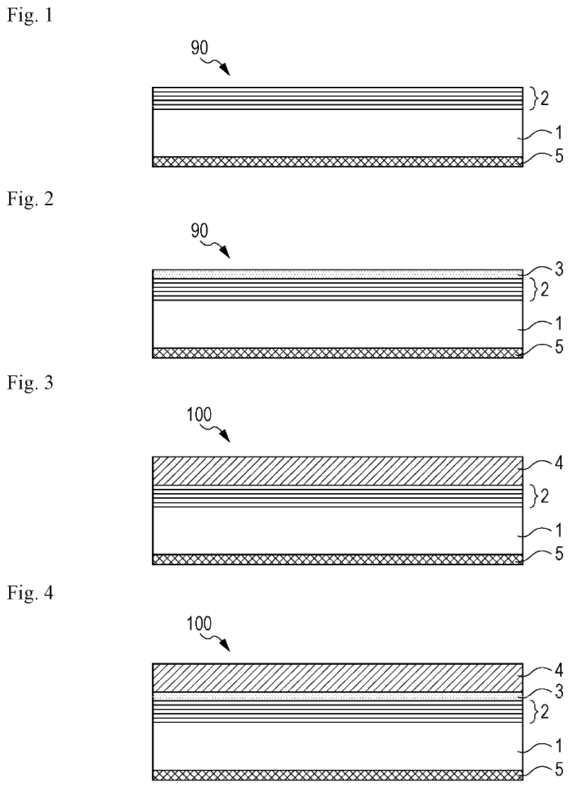

FIG. 1 is a schematic cross-sectional view illustrating an example of a substrate with a multilayer reflective film 90 of the present embodiment. The substrate with a multilayer reflective film 90 of the present embodiment includes a substrate 1 and a multilayer reflective film 2 formed on the substrate 1. As illustrated in FIGS. 7 to 12, the multilayer reflective film 2 includes a multilayer film in which a low refractive index layer 24 and a high refractive index layer 22 are alternately layered. As illustrated in FIGS. 7 to 12, the multilayer reflective film 2 further includes at least one intermediate layer 26 disposed between the low refractive index layer 24 and the high refractive index layer 22. A conductive back film 5 for electrostatic chuck may be formed on a back surface of the substrate 1 (surface opposite to a side where the multilayer reflective film 2 is formed).

FIG. 2 is a schematic cross-sectional view illustrating another example of the substrate with a multilayer reflective film 90 according to the present embodiment. The substrate with a multilayer reflective film 90 illustrated in FIG. 2 includes the substrate 1, the multilayer reflective film 2 formed on the substrate 1, and a protective film 3 formed on the multilayer reflective film 2. As illustrated in FIGS. 7 to 12, the multilayer reflective film 2 includes the low refractive index layer 24, the high refractive index layer 22, and at least one intermediate layer 26 disposed between the low refractive index layer 24 and the high refractive index layer 22. A conductive back film 5 for electrostatic chuck may be formed on a back surface of the substrate 1 (surface opposite to a side where the multilayer reflective film 2 is formed).

In the present specification, “a thin film B is disposed (formed) on a thin film A (or substrate)” includes not only a case where the thin film B is disposed (formed) in contact with a surface of the thin film A (or substrate) but also a case where there is another thin film C between the thin film A (or substrate) and the thin film B. In addition, in the present specification, for example, “a thin film B (or substrate) is disposed in contact with a surface of a thin film A” means that the thin film A (or substrate) and the thin film B are disposed in direct contact with each other without another thin film interposed between the thin film A (or substrate) and the thin film B. In addition, in the present specification, “on” does not necessarily mean an upper side in the vertical direction. “On” merely indicates a relative positional relationship among a thin film, the substrate 1, and the like.

The substrate with a multilayer reflective film 90 of the present embodiment will be specifically described.

### <Substrate 1>

As the substrate 1, a substrate having a low thermal expansion coefficient within a range of 0±5 ppb/° C. is preferably used in order to prevent distortion of a transfer pattern due to heat during exposure to EUV light. As a material having a low thermal expansion coefficient within this range, for example, SiO₂—TiO₂-based glass or multicomponent-based glass ceramic can be used.

A main surface (first main surface) of the substrate 1 on a side where a transfer pattern (absorber pattern 4a described later) is formed is preferably processed in order to increase a flatness. By increasing the flatness of the main surface of the substrate 1, position accuracy and transfer accuracy of the pattern can be increased. For example, in a case of EUV exposure, the flatness in a region of 132 mm×132 mm of the main surface of the substrate 1 on the side where the transfer pattern is formed is preferably 0.1 μm or less, more preferably 0.05 μm or less, and particularly preferably 0.03 μm or less. In addition, a second main surface (back surface) opposite to the side where the transfer pattern is formed is a surface to be fixed to an exposure apparatus by electrostatic chuck. The flatness in a region of 142 mm×142 mm of the back surface is preferably 0.1 μm or less, more preferably 0.05 μm or less, and particularly preferably 0.03 μm or less. Note that, in the present specification, the flatness is a value representing warpage (deformation amount) of a surface indicated by total indicated reading (TIR). The flatness (TIR) is an absolute value of a difference in height between the highest position of a surface of the substrate 1 above a focal plane and the lowest position of the surface of the substrate 1 below the focal plane, in which the focal plane is a plane defined by a minimum square method using the surface of the substrate 1 as a reference.

In a case of EUV exposure, the main surface of the substrate 1 on a side where the transfer pattern is formed preferably has a surface roughness of 0.1 nm or less in terms of root mean square roughness (Rq). Note that the surface roughness can be measured with an atomic force microscope.

The substrate 1 preferably has a high rigidity in order to prevent deformation of a thin film (such as the multilayer reflective film 2) formed on the substrate 1 due to a film stress. In particular, the substrate 1 preferably has a high Young's modulus of 65 GPa or more.

### <Multilayer Reflective Film 2>

As illustrated in FIGS. 1 and 2, the substrate with a multilayer reflective film 90 of the present embodiment includes the substrate 1 and the multilayer reflective film 2 formed on the substrate 1.

The multilayer reflective film 2 has a structure in which a plurality of layers mainly containing elements having different refractive indices is periodically layered. Generally, the multilayer reflective film 2 includes a multilayer film in which a thin film (high refractive index layer 22) of a light element that is a high refractive index material or a compound of the light element and a thin film (low refractive index layer 24) of a heavy element that is a low refractive index material or a compound of the heavy element are alternately layered.

The multilayer reflective film 2 of the substrate with a multilayer reflective film 90 of the present embodiment includes a multilayer film in which the low refractive index layer 24 and the high refractive index layer 22 containing silicon (Si) are alternately layered.

In the present embodiment, the high refractive index layer 22 is a layer containing silicon (Si). The high refractive index layer 22 may contain a Si simple substance or a Si compound. The Si compound may contain Si and at least one element selected from the group consisting of B, C, N, O, and H. By using the layer containing Si as the high refractive index layer 22, the multilayer reflective film 2 having an excellent reflectance with respect to EUV light can be obtained. In order to obtain a relatively high reflectance, the high refractive index layer 22 preferably contains silicon (Si). Note that “the high refractive index layer 22 contains silicon (Si)” does not exclude presence of impurities other than Si inevitably mixed in the high refractive index layer 22. The same applies to other thin films and other elements.

The content of silicon (Si) in the multilayer reflective film 2 of the present embodiment is preferably 50 atom % or more, and more preferably 65 atom % or more. In addition, the content of silicon (Si) in the multilayer reflective film 2 is preferably 99 atom % or less, and more preferably 95 atom % or less. Note that the content of silicon (Si) in the multilayer reflective film 2 is the total content of Si constituting the high refractive index layer 22 and the intermediate layer 26.

In the present embodiment, the low refractive index layer 24 can contain at least one element selected from the group consisting of Mo, Ru, Rh, and Pt, or can contain an alloy containing at least one element selected from the group consisting of Mo, Ru, Rh, and Pt.

The low refractive index layer 24 of the substrate with a multilayer reflective film 90 of the present embodiment preferably contains ruthenium (Ru). Examples of a material of the low refractive index layer 24 containing Ru include a Ru simple substance, RuRh, RuNb, RuMo, and the like. By inclusion of ruthenium (Ru) in the low refractive index layer 24, a shallow effective reflective surface can be obtained.

The content of an element constituting the low refractive index layer 24 in the multilayer reflective film 2 of the present embodiment is preferably 40 atom % or more, and more preferably 55 atom % or more. In addition, the content of an element constituting the low refractive index layer 24 in the multilayer reflective film 2 of the present embodiment is preferably 99 atom % or less, and more preferably 85 atom % or less. Note that, in a case where a plurality of elements constituting the low refractive index layer 24 is contained, the content of an element constituting the low refractive index layer 24 in the multilayer reflective film 2 is the total content of these elements.

As a node (minimum line width) to be transferred onto a transferred object such as a semiconductor substrate 60 is narrower, an influence of a 3D effect on transfer characteristics is larger. The 3D effect means that a three-dimensional structure including a structure of a reflective mask 200 in a height direction affects fidelity of a transfer pattern with respect to a mask pattern. In EUV lithography, in order to suppress the 3D effect, it is necessary to control a reflective surface of the reflective mask 200. As the control of the reflective surface, specifically, it is necessary to bring an effective reflective surface of the multilayer reflective film 2 as close as possible to a surface. By presence of the shallow effective reflective surface in the reflective mask 200, it is possible to control the EUV light reflected from the multilayer reflective film 2 so as not to spread, and therefore the 3D effect can be suppressed. By inclusion of a multilayer film in which the low refractive index layer 24 containing ruthenium (Ru) and the high refractive index layer 22 containing silicon (Si) are alternately layered in the multilayer reflective film 2, the effective reflective surface of the multilayer reflective film 2 can be made shallower than that of a conventional Mo/Si multilayer reflective film.

Meanwhile, when a material containing Ru is used as the low refractive index layer 24, there may be a problem that Si of the high refractive index layer 22 is diffused into the low refractive index layer 24 and a reflectance of the multilayer reflective film 2 with respect to EUV light decreases. In the present embodiment, as illustrated in FIGS. 7 to 12, by further inclusion of at least one predetermined intermediate layer 26 disposed between the low refractive index layer 24 and the high refractive index layer 22 in the multilayer reflective film 2, occurrence of this problem can be suppressed.

As illustrated in FIGS. 7 to 12, the multilayer reflective film 2 of the substrate with a multilayer reflective film 90 of the present embodiment further includes at least one intermediate layer 26 disposed between the low refractive index layer 24 and the high refractive index layer 22. By inclusion of the intermediate layer 26 in the multilayer reflective film 2, it is possible to suppress diffusion of Si in the high refractive index layer 22 into the low refractive index layer 24.

The multilayer reflective film 2 contains at least one additive element selected from nitrogen (N), carbon (C), and oxygen (O). Note that these elements can be contained in the intermediate layer 26. The intermediate layer 26 has a considerably thin film thickness. The film thickness of the intermediate layer 26 is 1.2 nm or less, for example, about 0.3 nm. When the intermediate layer 26 having such a film thickness is formed, a boundary between the intermediate layer 26 and the low refractive index layer 24 and/or a boundary between the intermediate layer 26 and the high refractive index layer 22 is not clearly determined in some cases. Therefore, it can be said that the predetermined additive element is an element to be added in order to form the intermediate layer 26 but is an element present in the multilayer reflective film 2 (in the intermediate layer 26, the low refractive index layer 24, and the high refractive index layer 22).

The film thickness of the intermediate layer 26 is preferably 0.1 nm to 1.2 nm, and more preferably 0.3 nm to 1.0 nm. The film thickness of the intermediate layer 26 is in the predetermined range, and therefore it is possible to more reliably suppress diffusion of Si in the high refractive index layer 22 into the low refractive index layer 24.

The content of the additive element in the multilayer reflective film 2 of the substrate with a multilayer reflective film 90 of the present embodiment is 40 atom % or less. When the content of the additive element is too large, a reflectance of the multilayer reflective film 2 with respect to EUV light may be adversely affected. In a case where the additive element is nitrogen (N), the content of the additive element (N) in the multilayer reflective film 2 is preferably 35 atom % or less, and more preferably 20 atom % or less. In a case where the additive element is carbon (C), the content of the additive element (C) in the multilayer reflective film 2 is preferably 40 atom % or less, and more preferably 30 atom % or less. In a case where the additive element is oxygen (O), the content of the additive element (O) in the multilayer reflective film 2 is preferably 15 atom % or less, and more preferably 10 atom % or less.

The content of the additive element in the multilayer reflective film 2 of the substrate with a multilayer reflective film 90 of the present embodiment is preferably 1 atom % or more. The content of the additive element in the multilayer reflective film 2 is the predetermined content, and therefore it is possible to more reliably suppress diffusion of Si in the high refractive index layer 22 into the low refractive index layer 24.

In order to more efficiently suppress diffusion of Si in the high refractive index layer 22 into the low refractive index layer 24, in a case where the additive element is nitrogen (N), the content of the additive element (N) in the multilayer reflective film 2 is preferably 5 atom % or more, and more preferably 10 atom % or more. In a case where the additive element is carbon (C), the content of the additive element (C) in the multilayer reflective film 2 is preferably 10 atom % or more, and more preferably 20 atom % or more. In a case where the additive element is oxygen (O), the content of the additive element (O) in the multilayer reflective film 2 is preferably 3 atom % or more, and more preferably 5 atom % or more.

The intermediate layer 26 of the multilayer reflective film 2 of the substrate with a multilayer reflective film 90 of the present embodiment preferably contains at least one selected from SiN, SiO, SiC, SiON, SiCN, SiOC, and SiOCN. The intermediate layer 26 is made of any one of these silicon compounds, and therefore the intermediate layer 26 disposed between the low refractive index layer 24 and the high refractive index layer 22 can more reliably suppress diffusion of Si in the high refractive index layer 22 into the low refractive index layer 24. In addition, the intermediate layer 26 can contain at least one boron compound selected from B₄C and BN. The intermediate layer 26 is preferably made of at least one selected from B₄C and BN. By inclusion of the predetermined boron compound in the intermediate layer 26, it is possible to more reliably suppress diffusion of Si in the high refractive index layer 22 into the low refractive index layer 24.

In order to form the multilayer reflective film 2, generally, the high refractive index layer 22 and the low refractive index layer 24 can be layered in this order from the substrate 1 side for a plurality of periods. In this case, one stack of (high refractive index layer 22/low refractive index layer 24) is one period. In the substrate with a multilayer reflective film 90 of the present embodiment, since the multilayer reflective film 2 includes the intermediate layer 26, the intermediate layer 26 can be appropriately disposed between the high refractive index layer 22 and the low refractive index layer 24.

As illustrated in FIG. 7, in a first aspect of the multilayer reflective film 2, a structure can be adopted in which the high refractive index layer 22, the intermediate layer 26, the low refractive index layer 24, and the intermediate layer 26 are layered in this order from the substrate 1 side for a plurality of periods. In this case, a structure of “high refractive index layer 22/intermediate layer 26/low refractive index layer 24/intermediate layer 26” is one unit (one period). FIG. 7 illustrates an example in which the multilayer reflective film 2 of the first aspect formed of one period is disposed on the substrate 1. In the first aspect, when the multilayer reflective film 2 formed of a plurality of periods is disposed on the substrate 1, a surface layer of an uppermost period (one period farthest from the substrate 1) is the intermediate layer 26 (Si-containing layer).

In a second aspect of the multilayer reflective film 2, a structure can be adopted in which the high refractive index layer 22, the intermediate layer 26, and the low refractive index layer 24 are layered in this order from the substrate 1 side for a plurality of periods. FIG. 8 illustrates an example in which the multilayer reflective film 2 of the second aspect formed of one period is disposed on the substrate 1. In this case, a structure of “high refractive index layer 22/intermediate layer 26/low refractive index layer 24” is one unit (one period). In the second aspect, when the multilayer reflective film 2 formed of a plurality of periods is disposed on the substrate 1, a surface layer of an uppermost period is the low refractive index layer 24.

In a third aspect of the multilayer reflective film 2, a structure can be adopted in which the high refractive index layer 22, the low refractive index layer 24, and the intermediate layer 26 are layered in this order from the substrate 1 side for a plurality of periods. FIG. 9 illustrates an example in which the multilayer reflective film 2 of the third aspect formed of one period is disposed on the substrate 1. In this case, a structure of “high refractive index layer 22/low refractive index layer 24/intermediate layer 26” is one unit (one period). In the third aspect, when the multilayer reflective film 2 formed of a plurality of periods is disposed on the substrate 1, a surface layer of an uppermost period is the intermediate layer 26 (Si-containing layer).

In a fourth aspect of the multilayer reflective film 2, a structure can be adopted in which the low refractive index layer 24, the intermediate layer 26, the high refractive index layer 22, and the intermediate layer 26 are layered in this order from the substrate 1 side for a plurality of periods. FIG. 10 illustrates an example in which the multilayer reflective film 2 of the fourth aspect formed of one period is disposed on the substrate 1. In this case, a structure of “low refractive index layer 24/intermediate layer 26/high refractive index layer 22/intermediate layer 26” is one unit (one period). In the fourth aspect, when the multilayer reflective film 2 formed of a plurality of periods is disposed on the substrate 1, a surface layer of an uppermost period is the intermediate layer 26 (Si-containing layer).

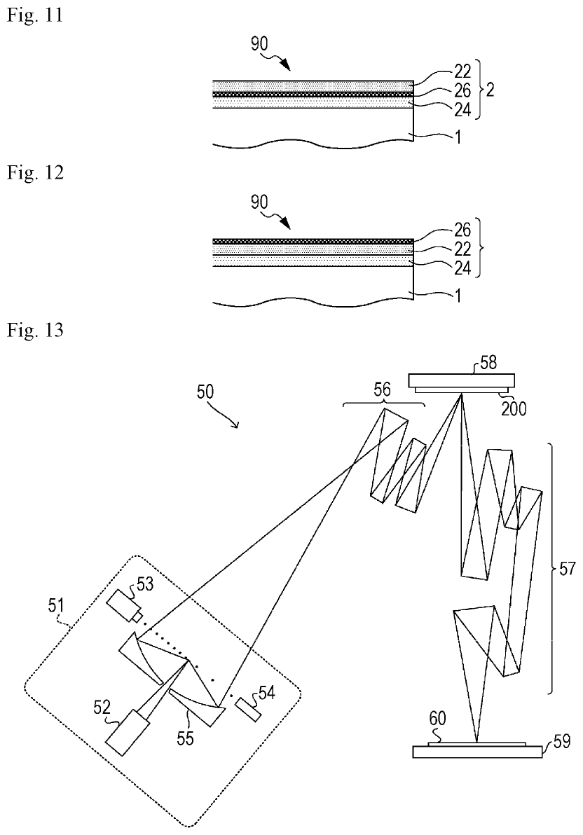

In a fifth aspect of the multilayer reflective film 2, a structure can be adopted in which low refractive index layer 24, the intermediate layer 26, and the high refractive index layer 22 are layered in this order from the substrate 1 side for a plurality of periods. FIG. 11 illustrates an example in which the multilayer reflective film 2 of the fifth aspect formed of one period is disposed on the substrate 1. In this case, a structure of “low refractive index layer 24/intermediate layer 26/high refractive index layer 22” is one unit (one period). In the fifth aspect, a surface layer of an uppermost period is the high refractive index layer 22.

In a sixth aspect of the multilayer reflective film 2, a structure can be adopted in which low refractive index layer 24, the high refractive index layer 22, and the intermediate layer 26 are layered in this order from the substrate 1 side for a plurality of periods. FIG. 12 illustrates an example in which the multilayer reflective film 2 of the sixth aspect formed of one period is disposed on the substrate 1. In this case, a structure of “low refractive index layer 24/high refractive index layer 22/intermediate layer 26” is one unit (one period). In the sixth aspect, a surface layer of an uppermost period is the intermediate layer 26 (Si-containing layer).

In the second aspect of the multilayer reflective film 2, for example, when the low refractive index layer 24 is a surface of the multilayer reflective film 2, it is preferable to further form a layer containing Si (Si-containing layer) similar to the high refractive index layer 22 on the low refractive index layer 24 of an uppermost period in order to suppress a temporal change. Note that the Si-containing layer can be at least a part of the protective film 3 described later. The protective film 3 described later may include the Si-containing layer.

In addition, in the first aspect or the like of the multilayer reflective film 2, the surface layer (intermediate layer 26) of the uppermost period can also be used as a Si-containing layer which is a part of the protective film 3 described later. In this case, the intermediate layer 26 of the surface layer is preferably made of SiN, SiC, or SiCN.

In the fifth aspect of the multilayer reflective film 2, when the surface layer of the uppermost period is the high refractive index layer 22, the protective film 3 can be formed on the high refractive index layer 22.

Next, a relationship between a material of the intermediate layer 26 and the Si-containing layer which is at least a part of the protective film 3 will be described. The Si-containing layer, a SiN material layer, and a SiC material layer in this description will be described in description of the protective film 3.

The material of the intermediate layer 26 and the material of the Si-containing layer can be the same. In addition, the Si-containing layer does not have to contain oxygen.

When the intermediate layer 26 is formed using SiN as a material, the Si-containing layer is preferably a SiN material layer or a SiC material layer. The Si-containing layer is more preferably a SiN material layer. In addition, the content of N in the SiN material layer is more preferably larger than the content of N in the intermediate layer 26. As a result, diffusion of Si into the protective film 3 described later can be suppressed.

When the intermediate layer 26 is formed using SiC as a material, the Si-containing layer is preferably a SiN material layer or a SiC material layer. The Si-containing layer is more preferably a SiC material layer. In addition, the content of C in the SiC material layer is more preferably larger than the content of C in the intermediate layer 26. As a result, diffusion of Si into the protective film 3 described later can be suppressed.

When the intermediate layer 26 is formed using SiO as a material, the Si-containing layer is preferably a SiN material layer or a SiC material layer. As a result, diffusion of Si into the protective film 3 described later can be suppressed.

The material of the intermediate layer 26 and the material of the Si-containing layer can be different.

When the intermediate layer 26 is formed using B₄C as a material, the Si-containing layer is preferably a SiN material layer or a SiC material layer. The Si-containing layer is more preferably a SiN material layer. As a result, it is possible to maintain a high reflectance while suppressing diffusion between the high refractive index layer 22 and the low refractive index layer 24.

In a case where the low refractive index layer 24 of the substrate with a multilayer reflective film 90 of the present embodiment contains ruthenium (Ru), when a stack including one low refractive index layer 24 and one high refractive index layer 22 is taken as one period, the stack is preferably layered for less than 40 periods. When the low refractive index layer 24 contains Ru, the stack is preferably layered for 35 periods or less in the multilayer reflective film 2. Since the effective reflective surface of the multilayer reflective film 2 of the present embodiment is shallow, an appropriate reflectance can be obtained with a smaller number of periods than that of a conventional multilayer reflective film. Therefore, by using the substrate with a multilayer reflective film 90 of the present embodiment, the 3D effect can be suppressed. Note that in order to make the multilayer reflective film 2 to have an appropriate reflectance, the stack is layered preferably for 20 periods or more, more preferably for 25 periods or more.

When the high refractive index layer 22 of the multilayer reflective film 2 is amorphous and the low refractive index layer 24 of the multilayer reflective film 2 is amorphous, diffusion of Si in the high refractive index layer 22 is easy. Therefore, when the high refractive index layer 22 of the multilayer reflective film 2 is amorphous, the low refractive index layer 24 of the multilayer reflective film 2 preferably has a crystal structure having crystallinity. When the low refractive index layer 24 has the crystal structure, the film thickness of the low refractive index layer 24 is preferably 2.5 nm or more and 3.5 nm or less.

When the low refractive index layer 24 of the multilayer reflective film 2 of the present embodiment contains ruthenium (Ru), an uppermost layer of the multilayer reflective film 2 can be the low refractive index layer 24. This is because Ru has a function of protecting the multilayer reflective film 2 from dry etching and cleaning in a reflective mask 200 manufacturing process described later. In this case, the low refractive index layer 24 as the uppermost layer of the multilayer reflective film 2 can also function as the protective film 3.

The reflectance of the multilayer reflective film 2 alone used in the present embodiment is, for example, 65% or more. An upper limit of the reflectance of the multilayer reflective film 2 is, for example, 73%. Note that the thicknesses and period of layers included in the multilayer reflective film 2 can be selected so as to satisfy Bragg's law. In a case of the multilayer reflective film 2 for reflecting EUV light having a wavelength of 13.5 nm, the film thickness of one period (one pair of the high refractive index layer 22 and the low refractive index layer 24 and at least one intermediate layer 26) is preferably about 7 nm.

The multilayer reflective film 2 can be formed by a known method. The multilayer reflective film 2 can be formed by, for example, an ion beam sputtering method or a magnetron sputtering method such as a DC sputtering method or an RF sputtering method. The magnetron sputtering method is preferable because the high refractive index layer 22, the low refractive index layer 24, and the intermediate layer 26 can be continuously formed.

The intermediate layer 26 can be formed by a magnetron sputtering method (reactive sputtering method) in a predetermined gas atmosphere using a Si target. In addition, the intermediate layer 26 can be formed by a magnetron sputtering method using a SiN sintered body, a SiC sintered body, or a SiO sintered body as a target. When the SiN sintered body, the SiC sintered body, or the SiO sintered body is prepared, an oxide of at least one metal selected from magnesium (Mg), aluminum (Al), titanium (Ti), yttrium (Y), and zirconium (Zr) can be added as a sintering aid. By adding a sintering aid, a sintered body having a high density can be prepared. The intermediate layer 26 thus formed contains an oxide of the above metal added as a sintering aid.

The multilayer reflective film 2 can contain an oxide of at least one metal selected from magnesium (Mg), aluminum (Al), titanium (Ti), yttrium (Y), and zirconium (Zr). The content of the above metal (at least one metal selected from Mg, Al, Ti, Y, and Zr) in the multilayer reflective film 2 is preferably 0.05 atom % to 3.0 atom %, and more preferably 0.1 atom % to 2.5 atom %.

For example, when the multilayer reflective film 2 is a Si/SiN/Ru multilayer film using Si as the high refractive index layer 22, SiN as the intermediate layer 26, and Ru as the low refractive index layer 24, a Si film (high refractive index layer 22) having a film thickness of about 3.9 nm is formed on the substrate 1 in a Kr gas atmosphere using a Si target by a magnetron sputtering method. Next, a SiN film (intermediate layer 26) having a film thickness of about 0.3 nm is formed in a Kr gas and nitrogen gas atmosphere using a Si target by magnetron sputtering (reactive sputtering). Next, a Ru film (low refractive index layer 24) having a film thickness of about 2.8 nm is formed in a Kr gas atmosphere using a Ru target by a magnetron sputtering method. By repeating such an operation, the multilayer reflective film 2 in which a Si/SiN/Ru film is layered for 20 to 39 periods can be formed. The total film thickness of the Si/SiN/Ru film for one period is preferably 7 nm.

### <Protective Film 3>

As illustrated in FIG. 2, the substrate with a multilayer reflective film 90 of the present embodiment preferably includes the protective film 3 on the multilayer reflective film 2.

The protective film 3 can be formed on the multilayer reflective film 2 or in contact with a surface of the multilayer reflective film 2 in order to protect the multilayer reflective film 2 from dry etching and cleaning in a reflective mask 200 manufacturing process described later. In addition, the protective film 3 has a function of protecting the multilayer reflective film 2 when a black defect in a transfer pattern (absorber pattern 4a) is corrected using an electron beam (EB). By forming the protective film 3 on the multilayer reflective film 2, damage to the surface of the multilayer reflective film 2 can be suppressed when the reflective mask 200 is manufactured. As a result, a reflectance characteristic of the multilayer reflective film 2 with respect to EUV light is improved.

FIG. 2 illustrates a case where the protective film 3 has one layer. However, the protective film 3 can have a stack of two layers. In addition, the protective film 3 can have a stack of three or more layers, a lowermost layer and an uppermost layer may be made of, for example, a substance containing ruthenium (Ru), and a metal other than Ru or an alloy may be interposed between the lowermost layer and the uppermost layer. The protective film 3 is made of, for example, a material containing ruthenium (Ru) as a main component. Examples of the material containing Ru as a main component include a Ru metal simple substance, a Ru alloy containing Ru and at least one metal selected from titanium (Ti), niobium (Nb), rhodium (Rh), molybdenum (Mo), zirconium (Zr), yttrium (Y), boron (B), lanthanum (La), cobalt (Co), and rhenium (Re), and a material further containing nitrogen in addition to a Ru metal simple substance or a Ru alloy. The protective film 3 is made of, for example, a material containing rhodium (Rh) as a main component. Examples of the material containing Rh as a main component include a Rh metal simple substance, a Rh alloy containing Rh and at least one metal selected from titanium (Ti), niobium (Nb), ruthenium (Ru), molybdenum (Mo), zirconium (Zr), yttrium (Y), boron (B), lanthanum (La), cobalt (Co), and rhenium (Re), and a material further containing nitrogen in addition to a Rh metal simple substance or a Rh alloy.

A Ru content ratio of the Ru alloy used for the protective film 3 is 50 atom % or more and less than 100 atom %, preferably 80 atom % or more and less than 100 atom %, and more preferably 95 atom % or more and less than 100 atom %. A Rh content ratio of the Rh alloy used for the protective film 3 is 50 atom % or more and less than 100 atom %, preferably 80 atom % or more and less than 100 atom %, and more preferably 95 atom % or more and less than 100 atom %. The protective film 3 in this case can have mask cleaning resistance, an etching stopper function when an absorber film 4 is etched, and a function of preventing the multilayer reflective film 2 from changing with time while sufficiently ensuring a reflectance with respect to EUV light.

The protective film 3 in the substrate with a multilayer reflective film 90 of the present embodiment preferably contains the same material as the low refractive index layer 24. In addition, the protective film 3 in the substrate with a multilayer reflective film 90 of the present embodiment more preferably contains at least one selected from ruthenium (Ru) and rhodium (Rh).

As described above, the low refractive index layer 24 preferably contains ruthenium (Ru). Therefore, the protective film 3 preferably contains the same material (Ru) as the low refractive index layer 24. In the substrate with a multilayer reflective film 90 of the present embodiment, by inclusion of the same material as the low refractive index layer 24 in the protective film 3, it can be expected that the protective film 3 functions as a part of the multilayer reflective film 2. Therefore, improvement of the reflectance of the multilayer reflective film 2 can be expected. In addition, by using the same material as the low refractive index layer 24, the protective film 3 can be more easily formed. Note that the protective film 3 is more preferably made of a material having the same elements and the same composition ratio as those of the low refractive index layer 24.

The film thickness of the protective film 3 is not particularly limited as long as the function as the protective film 3 can be achieved. From the viewpoint of the reflectance for EUV light, the film thickness of the protective film 3 is preferably 1.0 nm to 8.0 nm and more preferably 1.5 nm to 6.0 nm.

As a method for forming the protective film 3, it is possible to adopt a known film forming method without any particular limitation. Specific examples of the method for forming the protective film 3 include an ion beam sputtering method, a magnetron sputtering method such as a DC sputtering method or an RF sputtering method, a vapor phase growth method (CVD), and a vacuum vapor deposition method.

In the substrate with a multilayer reflective film 90 of the present embodiment, the protective film 3 can include a Si-containing layer and a protective layer. The Si-containing layer of the protective film 3 is formed on a side in contact with the multilayer reflective film 2, and the protective layer is formed on the Si-containing layer. Note that the protective layer can be made of a material similar to that of the protective film 3 described above, and can be a thin film having a function similar to that of the protective film 3.

The protective film 3 in the substrate with a multilayer reflective film 90 of the present embodiment preferably includes the Si-containing layer on a side in contact with the multilayer reflective film 2. The Si-containing layer preferably includes a silicon (Si) simple substance layer, a SiN material layer containing silicon (Si) and nitrogen (N), a SiC material layer containing silicon (Si) and carbon (C), or a SiNC layer containing silicon (Si), nitrogen (N), and carbon (C). By inclusion of the predetermined Si-containing layer (a SiN material layer, a SiC material layer, or a SiNC layer) in the protective film 3, diffusion of Si into the protective layer can be prevented. Therefore, it is possible to prevent a reflectance of the multilayer reflective film 2 with respect to the EUV light from being largely reduced as compare with a calculated value.

The Si-containing layer in the protective film 3 can include a plurality of layers having different compositions. For example, the Si-containing layer can include two layers consisting of a layer containing Si, formed in contact with the multilayer reflective film 2, and a layer containing Si and an additive element, formed on the layer containing Si. The layer containing Si can be a layer (Si layer) containing only Si. The layer containing Si and an additive element can be a layer containing only Si and the additive element. The additive element is preferably nitrogen (N) and/or carbon (C). The Si-containing layer more preferably includes two layers consisting of a Si layer and a SiN layer, a SiC layer, or a SiNC layer. In addition, a composition-inclined film may be adopted in which a composition is inclined such that the amount of the additive element increases in a film thickness direction from the multilayer reflective film 2 side to the protective layer side. When the Si-containing layer is formed of the predetermined two layers or the composition-inclined film, diffusion of Si into the protective layer can be suppressed, and a reflectance of the multilayer reflective film 2 with respect to EUV light can be increased.

The SiN material layer is a layer containing silicon (Si) and nitrogen (N). The SiN material layer may further contain another element, for example, O, C, B, and/or H. The SiN material layer may contain, for example, at least one material selected from silicon nitride (SiₓN_{y} (x and y are integers of 1 or more)) and silicon oxynitride (SiₓO_{y}N_{z} (x, y, and z are integers of 1 or more.)). The SiN material layer may contain, for example, at least one material selected from SiN, Si₃N₄, and SiON.

The SiC material layer is a layer containing silicon (Si) and carbon (C). The SiC material layer may further contain another element, for example, O, N, B, and/or H. The SiC material layer contains, for example, silicon carbide (SiC).

When Si contained in the Si-containing layer is diffused into the protective layer by heating during EUV exposure, a metal (for example, Ru) contained in the protective layer may be bonded to Si to form a metal silicide. When a metal silicide is formed in the protective layer, there is a problem that a reflectance of the multilayer reflective film 2 with respect to EUV light is largely reduced as compare with a calculated value (a calculated value when it is assumed that there is no diffusion of Si). According to the substrate with a multilayer reflective film 90 of the present embodiment, since the Si-containing layer is a SiN material layer or a SiC material layer, diffusion of Si into the protective layer can be prevented by presence of the Si-containing layer. Therefore, it is possible to prevent a metal silicide (for example, RuSi) from being formed in the protective layer. As a result, it is possible to prevent a reflectance of the multilayer reflective film 2 with respect to EUV light from being largely reduced as compare with the calculated value.

By heating during annealing at the time of manufacturing a reflective mask blank 100, oxygen (O₂) in the atmosphere may pass through the protective layer and may be bonded to Si to form a layer containing SiO₂. When the SiO₂ layer is formed in the protective film 3 in this manner, there is a problem that blister resistance (H₂ resistance) of a reflective mask 200 in an exposure machine deteriorates. According to the substrate with a multilayer reflective film 90 of the present embodiment, it is possible to prevent a SiO₂ layer from being formed in the protective film 3. As a result, it is possible to prevent blister resistance (H₂ resistance) of the reflective mask 200 in the exposure machine from deteriorating.

The content of N in the SiN material layer is preferably 5 atom % to 35 atom %, and more preferably 10 atom % to 20 atom %. When the content of N in the SiN material layer is less than 5 atom %, an effect of preventing Si from being diffused into the protective layer cannot be sufficiently obtained. When the content of N in the SiN material layer exceeds 35 atom %, a film density of the SiN material layer is reduced, durability is rather deteriorated, and a reflectance is also reduced.

The content of C in the SiC material layer is preferably 10 atom % to 40 atom %, and more preferably 20 atom % to 30 atom %. When the content of C in the SiC material layer is less than 10 atom %, an effect of preventing Si from being diffused into the protective layer cannot be sufficiently obtained. When the content of C in the SiC material layer exceeds 40 atom %, a film density of the SiC material layer is reduced, and durability is rather deteriorated.

### <Absorber Film 4>

The reflective mask blank 100 of the present embodiment includes the absorber film 4 on the multilayer reflective film 2 of the above-described substrate with a multilayer reflective film 90 or on the protective film 3 formed in contact with a surface of the multilayer reflective film 2.

FIG. 3 is a schematic cross-sectional view illustrating an example of the reflective mask blank 100 of the present embodiment. The reflective mask blank 100 illustrated in FIG. 3 includes the absorber film 4 for absorbing EUV light on the multilayer reflective film 2 of the substrate with a multilayer reflective film 90 illustrated in FIG. 1. Note that the reflective mask blank 100 can further include another thin film such as a resist film 11 on the absorber film 4. In a case of the structure illustrated in FIG. 3, an uppermost layer of the multilayer reflective film 2 can be the low refractive index layer 24 containing Ru.

FIG. 4 is a schematic cross-sectional view illustrating another example of the reflective mask blank 100 of the present embodiment. The reflective mask blank 100 illustrated in FIG. 4 includes the absorber film 4 for absorbing EUV light on the protective film 3 of the substrate with a multilayer reflective film 90 illustrated in FIG. 2. Note that the reflective mask blank 100 can further include another thin film such as a resist film 11 on the absorber film 4.

FIG. 5 is a schematic cross-sectional view illustrating another example of the reflective mask blank 100 of the present embodiment. As illustrated in FIG. 5, the reflective mask blank 100 can include an etching mask film 6 on the absorber film 4. Note that the reflective mask blank 100 can further include another thin film such as the resist film 11 on the etching mask film 6.

In the reflective mask blank 100 of the present embodiment, since the absorber film 4 can absorb EUV light, the reflective mask 200 (EUV mask) of the present disclosure can be manufactured by patterning the absorber film 4 of the reflective mask blank 100. With the reflective mask blank 100 of the present embodiment, it is possible to obtain the reflective mask blank 100 including the multilayer reflective film 2 having a shallow effective reflective surface and capable of suppressing a phenomenon that atoms to be a material are diffused between the low refractive index layer 24 and the high refractive index layer 22.

A basic function of the absorber film 4 is to absorb EUV light. The absorber film 4 may be the absorber film 4 for the purpose of absorbing EUV light, or may be the absorber film 4 having a phase shift function in consideration of a phase difference of EUV light. The absorber film 4 having a phase shift function absorbs EUV light and reflects a part of the EUV light to shift a phase. That is, in the reflective mask 200 in which the absorber film 4 having a phase shift function is patterned, in a portion where the absorber film 4 is formed, a part of light is reflected at a level that does not adversely affect pattern transfer while EUV light is absorbed and attenuated. In addition, in a region (field portion) where the absorber film 4 is not formed, EUV light is reflected by the multilayer reflective film 2 (via the protective film 3 when there is the protective film 3). Therefore, a desired phase difference is generated between reflected light from the absorber film 4 having a phase shift function and reflected light from the field portion. The absorber film 4 having a phase shift function is preferably formed such that a phase difference between reflected light from the absorber film 4 and reflected light from the multilayer reflective film 2 is 170 to 260 degrees. Beams of the light having a reversed phase difference interfere with each other at a pattern edge portion, and an image contrast of a projected optical image is thereby improved. As the image contrast is improved, resolution is increased, and various exposure-related margins such as an exposure margin and a focus margin can be increased.

The absorber film 4 may be a single layer film or a multilayer film including a plurality of films (for example, a lower absorber film and an upper absorber film). In a case of a single layer film, the number of steps at the time of manufacturing the mask blank can be reduced, and manufacturing efficiency is increased. In a case of a multilayer film, an optical constant and film thickness of an upper absorber film can be appropriately set such that the upper absorber film serves as an antireflection film at the time of mask pattern defect inspection using light. This improves inspection sensitivity at the time of mask pattern defect inspection using light. In addition, when a film containing oxygen (O), nitrogen (N), and the like that improve oxidation resistance is used as the upper absorber film, temporal stability is improved. As described above, by forming the absorber film 4 into a multilayer film, various functions can be added to the absorber film 4. When the absorber film 4 has a phase shift function, by forming the absorber film 4 into a multilayer film, a range of adjustment on an optical surface can be increased, and therefore a desired reflectance can be easily obtained.

A material of the absorber film 4 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 3. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. The compound may contain the metal or alloy and oxygen (O), nitrogen (N), carbon (C), and/or boron (B).

The absorber film 4 can be formed by a magnetron sputtering method such as a DC sputtering method or an RF sputtering method. For example, the absorber film 4 such as a tantalum compound can be formed by a reactive sputtering method using a target containing tantalum and boron and using an argon gas containing oxygen or nitrogen.

In addition, a crystalline state of the absorber film 4 is preferably an amorphous or microcrystalline structure from a viewpoint of smoothness and flatness. When a surface of the absorber film 4 is not smooth or flat, the absorber pattern 4a may have a large edge roughness and a poor pattern dimensional accuracy. The absorber film 4 has a surface roughness of preferably 0.5 nm or less, more preferably 0.4 nm or less, still more preferably 0.3 nm or less in terms of root mean square roughness (Rms).

### <Etching Mask Film 6>

As illustrated in FIG. 5, the reflective mask blank 100 of the present embodiment can include the etching mask film 6 on the absorber film 4. As a material of the etching mask film 6, a material having a high etching selective ratio (etching rate of absorber film 4/etching rate of etching mask film 6) of the absorber film 4 to the etching mask film 6 is preferably used. The etching selective ratio of the absorber film 4 to the etching mask film 6 is preferably 1.5 or more, and more preferably 3 or more.

The reflective mask blank 100 of the present embodiment preferably includes the etching mask film 6 on the absorber film 4.

As a material of the etching mask film 6, chromium or a chromium compound is preferably used. Examples of the chromium compound include a material containing Cr and at least one element selected from N, O, C, and H. The etching mask film 6 more preferably contains CrN, CrO, CrC, CrON, CrOC, CrCN, or CrOCN, and is still more preferably a CrO-based film containing chromium and oxygen (CrO film, CrON film, CrOC film, or CrOCN film).

As the material of the etching mask film 6, tantalum or a tantalum compound is preferably used. Examples of the tantalum compound include a material containing Ta and at least one element selected from N, O, B, and H. The etching mask film 6 more preferably contains TaN, TaO, TaON, TaBN, TaBO, or TaBON.

As the material of the etching mask film 6, silicon or a silicon compound is preferably used. Examples of the silicon compound include a material containing Si and at least one element selected from N, O, C, and H, a metallic silicon containing a metal in silicon or a silicon compound (metal silicide), a metal silicon compound (metal silicide compound), and the like. Examples of the metal silicon compound include a material containing a metal, Si, and at least one element selected from N, O, C, and H.

The film thickness of the etching mask film 6 is preferably 3 nm or more in order to accurately form a pattern on the absorber film 4. In addition, the film thickness of the etching mask film 6 is preferably 15 nm or less in order to reduce the film thickness of the resist film 11.

### <Conductive Back Film 5>

The conductive back film 5 for electrostatic chuck can be formed on a back surface of the substrate 10 (surface opposite to a side where the multilayer reflective film 2 is formed). Sheet resistance required for the conductive back film 5 for electrostatic chuck is usually 100Ω/□ (Ω/square) or less. The conductive back film 5 can be formed, for example, by a magnetron sputtering method or an ion beam sputtering method using a target of a metal such as chromium or tantalum or an alloy thereof. A material of the conductive back film 5 is preferably a material containing chromium (Cr) or tantalum (Ta). For example, the material of the conductive back film 5 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. In addition, the material of the conductive back film 5 is preferably Ta (tantalum), an alloy containing Ta, or a Ta compound containing either Ta or an alloy containing Ta and at least one of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

The film thickness of the conductive back film 5 is not particularly limited as long as the conductive back film 5 functions as a film for electrostatic chuck. The film thickness of the conductive back film 5 is, for example, 10 nm to 200 nm.

### <Reflective Mask 200>

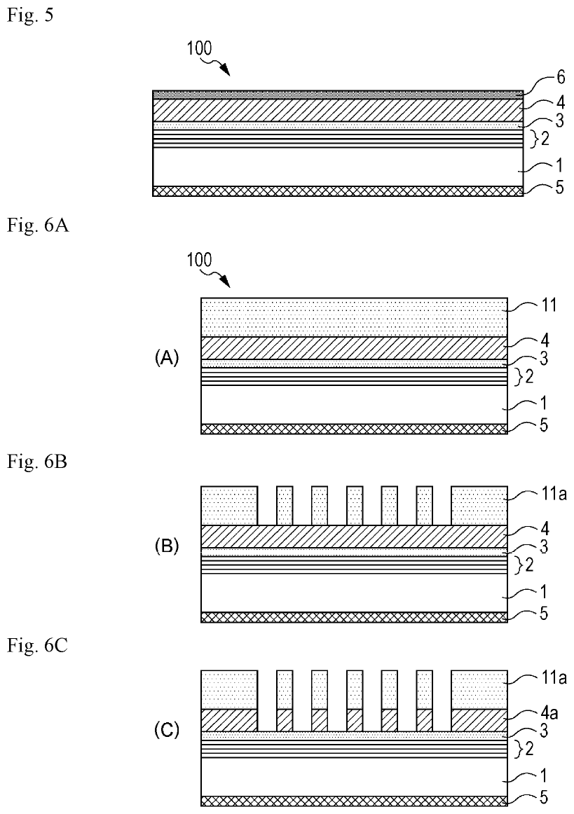

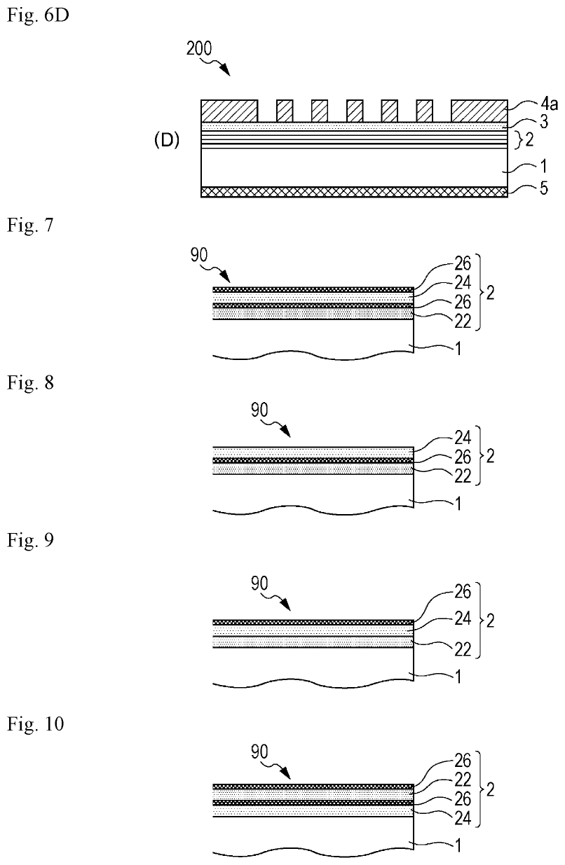

As illustrated in FIG. 6D, the reflective mask 200 of the present embodiment has the absorber pattern 4a obtained by patterning the absorber film 4 of the above-described reflective mask blank 100.

FIGS. 6A to 6D are schematic views illustrating an example of a method for manufacturing the reflective mask 200. Using the above-described reflective mask blank 100 of the present embodiment, the reflective mask 200 of the present embodiment can be manufactured. Hereinafter, an example of a method for manufacturing the reflective mask 200 will be described.

First, the reflective mask blank 100 including the substrate 1, the multilayer reflective film 2 formed on the substrate 1, the protective film 3 formed on the multilayer reflective film 2, and the absorber film 4 formed on the protective film 3 is prepared. Next, the resist film 11 is formed on the absorber film 4 to obtain the reflective mask blank 100 with the resist film 11 (FIG. 6A). A pattern is drawn on the resist film 11 with an electron beam drawing device, and then the resulting product is subjected to a development and rinse step to form a resist pattern 11a (FIG. 6B).

The absorber film 4 is dry-etched using the resist pattern 11a as a mask. As a result, a portion not covered with the resist pattern 11a in the absorber film 4 is etched to form the absorber pattern 4a (FIG. 6C).

As an etching gas for the absorber film 4, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, and the like can be used. As the chlorine-based gas, Cl₂, SiCl₄, CHCl₃, CCl₄, BCl₃, or the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 4a is formed, the resist pattern 11a is removed with a resist peeling liquid. After the resist pattern 11a is removed, the resulting product is subjected to a wet cleaning step using an acidic or alkaline aqueous solution to obtain the reflective mask 200 of the present embodiment (FIG. 6D).

Note that, when the reflective mask blank 100 in which the etching mask film 6 is formed on the absorber film 4 is used, a step of forming a pattern (etching mask pattern) on the etching mask film 6 using the resist pattern 11a as a mask and then forming a pattern on the absorber film 4 using the etching mask pattern as a mask is added.

The reflective mask 200 thus obtained has a structure in which the multilayer reflective film 2, the protective film 3, and the absorber pattern 4a are layered on the substrate 1.

A region where the multilayer reflective film 2 (including the protective film 3) is exposed has a function of reflecting EUV light. A region in which the multilayer reflective film 2 (including the protective film 3) is covered with the absorber pattern 4a has a function of absorbing EUV light. The reflective mask 200 of the present embodiment includes the multilayer reflective film 2 having a shallow effective reflective surface and capable of suppressing a phenomenon that atoms to be a material are diffused between the low refractive index layer 24 and the high refractive index layer 22. Therefore, by using the reflective mask 200 of the present embodiment, a finer pattern can be transferred onto a transferred object.

### <Method for Manufacturing Semiconductor Device>

A method for manufacturing a semiconductor device of the present embodiment includes a step of performing a lithography process using an exposure apparatus using the above-described reflective mask 200 to form a transfer pattern on a transferred object.

A transfer pattern can be formed on the semiconductor substrate 60 (transferred object) by lithography using the reflective mask 200 of the present embodiment. This transfer pattern has a shape obtained by transferring a pattern of the reflective mask 200. By forming a transfer pattern on the semiconductor substrate 60 with the reflective mask 200, a semiconductor device can be manufactured.

According to the present embodiment, it is possible to manufacture a semiconductor device using the reflective mask 200 including the multilayer reflective film 2 having a shallow effective reflective surface and capable of suppressing a phenomenon that atoms to be a material are diffused between the low refractive index layer 24 and the high refractive index layer 22. Therefore, by using the reflective mask 200 of the present embodiment, it is possible to increase the density and accuracy of the semiconductor device.

A method for transferring a pattern onto the semiconductor substrate 60 with resist using EUV light will be described with reference to FIG. 13.

FIG. 13 illustrates a schematic configuration of an EUV exposure apparatus 50 that is an apparatus for transferring a transfer pattern onto a resist film formed on the semiconductor substrate 60. In the EUV exposure apparatus 50, an EUV light generation unit 51, an irradiation optical system 56, a reticle stage 58, a projection optical system 57, and a wafer stage 59 are precisely arranged along an optical path axis of EUV light. A container of the EUV exposure apparatus 50 is filled with a hydrogen gas.

The EUV light generation unit 51 includes a laser light source 52, a tin droplet generation unit 53, a catching unit 54, and a collector 55. When a tin droplet emitted from the tin droplet generation unit 53 is irradiated with a high-power carbon dioxide laser from the laser light source 52, tin in a droplet state is turned into plasma to generate EUV light. The generated EUV light is collected by the collector 55, passes through the irradiation optical system 56, and enters the reflective mask 200 set on the reticle stage 58. The EUV light generation unit 51 generates, for example, EUV light having a wavelength of 13.53 nm.

EUV light reflected by the reflective mask 200 is usually reduced to about ¼ of pattern image light by the projection optical system 57 and projected on the semiconductor substrate 60 (transferred substrate). As a result, a given circuit pattern is transferred onto the resist film on the semiconductor substrate 60. The resist film that has been subjected to exposure is developed, whereby a resist pattern can be formed on the semiconductor substrate 60. By etching the semiconductor substrate 60 using the resist pattern as a mask, an integrated circuit pattern can be formed on the semiconductor substrate 60. A semiconductor device is manufactured through such a step and other necessary steps.

### Examples

Hereinafter, Examples and Comparative Example will be described with reference to the drawings.

(Preparation of Substrates with Multilayer Reflective Film 90 of Examples 1 to 8)

First, the 6025 size (about 152 mm×152 mm×6.35 mm) substrate 1 in which a first main surface and a second main surface were polished was prepared. The substrate 1 is a substrate made of low thermal expansion glass (SiO₂—TiO₂-based glass). The main surfaces of the substrate 1 were polished through a rough polishing step, a precision polishing step, a local processing step, and a touch polishing step.

Next, the multilayer reflective film 2 (see FIG. 8) including the high refractive index layer 22, the intermediate layer 26, and the low refractive index layer 24 was formed on the main surface (first main surface) of the substrate 1. In Examples 1 to 8, a material of the high refractive index layer 22 is Si, and a material of the low refractive index layer 24 is Ru. Table 1 presents a material and a film thickness of each of the intermediate layers 26 of Examples 1 to 8. In addition, the type of an additive element added at the time of forming the intermediate layer 26 and the content (atom %) of the additive element in the multilayer reflective film 2 are presented in “additive element content (atom %) in multilayer reflective film” in Table 1.

The multilayer reflective film 2 was formed by alternately building up the high refractive index layer 22, the intermediate layer 26, and the low refractive index layer 24 on the substrate 1 in contact with the substrate 1 by a DC magnetron sputtering method (reactive sputtering method) in a predetermined gas atmosphere using a Si target and a Ru target. First, the high refractive index layer 22 formed of a Si film was formed so as to have a film thickness presented in Table 1 using a Si target in a Kr gas atmosphere so as to be in contact with the main surface of the substrate 1.

Next, the intermediate layer 26 was formed so as to have a film thickness presented in Table 1. As presented in Table 1, a SiN film or a SiC film were used as the intermediate layer 26. The SiN film was formed using a Si target in a mixed gas atmosphere of a Kr gas and a N₂ gas. The SiC film was formed using a SiC target in a Kr gas atmosphere.

Next, the low refractive index layer 24 formed of a Ru film was formed. The Ru film was formed with a film thickness of 2.8 nm using a Ru target in a Kr gas atmosphere.

The multilayer reflective film 2 was formed by building up 35 periods (sets) on the main surface of the substrate 1 when one high refractive index layer 22, one intermediate layer 26, and one low refractive index layer 24 were taken as one period (one set).

Next, the protective film 3 including a Si-containing layer and a protective layer was formed on each of the multilayer reflective films 2 of Examples 1 to 8.

As presented in Table 1, the Si-containing layer of each of the protective films 3 of Examples 1 to 6 is formed of a Si film. The Si film was formed with a film thickness of 3.5 nm in a Kr gas atmosphere using a Si target by a DC magnetron sputtering method.

As presented in Table 1, the Si-containing layer of Example 7 includes two layers consisting of a Si film and a SiN film. First, the Si film was formed on the multilayer reflective film 2. The Si was formed with a film thickness of 3.2 nm in a Kr gas atmosphere using a Si target by a DC magnetron sputtering method. Next, the SiN film was formed. The SiN film was formed with a film thickness of 0.3 nm in a mixed gas atmosphere of a Kr gas and a N₂ gas using a Si target by a DC magnetron sputtering method (reactive sputtering method).

As presented in Table 1, the Si-containing layer of Example 8 includes two layers consisting of a Si film and a SiC film. First, the Si film was formed on the multilayer reflective film 2. The Si was formed with a film thickness of 2.9 nm in a Kr gas atmosphere using a Si target by a DC magnetron sputtering method. Next, the SiC layer was formed. The SiC film was formed with a film thickness of 0.6 nm in a Kr gas atmosphere using a SiC target by a DC magnetron sputtering method.

Next, a Ru film was formed as a protective layer on the Si-containing layer. The Ru film was formed with a film thickness of 3.5 nm in a Kr gas atmosphere using a Ru target.

The substrates with a multilayer reflective film 90 of Examples 1 to 8 were manufactured as described above.

(Preparation of Substrate with Multilayer Reflective Film 90 of Comparative Example 1)

A substrate with a multilayer reflective film 90 of Comparative Example 1 was manufactured in a similar manner to Example 1 except that the intermediate layer 26 in the multilayer reflective film 2 was not formed. Note that, in Comparative Example 1, the film thickness of the high refractive index layer was 4.2 nm, and the film thickness of the multilayer reflective film for one period was 7 nm in a similar manner to Example 1.

(Evaluation of Substrate with Multilayer Reflective Film 90)

Cross sections of the multilayer reflective films 2 manufactured under conditions similar to those of the multilayer reflective films 2 of Examples 1 to 8 were observed with a transmission electron microscope (TEM). As a result of TEM observation, it was confirmed that the intermediate layer 26 was formed between the high refractive index layer 22 and the low refractive index layer 24 of each of the multilayer reflective films 2 of Examples 1 to 8. Table 1 presents the content of an additive element in the multilayer reflective film 2 measured by energy dispersive X-ray analysis (EDX). Note that, for the content of the additive element in the multilayer reflective film 2, a maximum value of the additive element in a line profile in a cross-sectional direction by TEM-EDX analysis excluding a surface layer 5 nm of the multilayer reflective film 2 was measured.

Using the substrates with a multilayer reflective film 90 of Examples and Comparative Examples prepared as described above, a change in reflectance due to heat treatment to the substrates with a multilayer reflective film 90 was measured.

Specifically, first, a reflectance (R1, unit: %) of each of the substrates with a multilayer reflective film 90 of Examples and Comparative Examples with respect to EUV light (wavelength: 13.5 nm) was measured. Next, the substrate with a multilayer reflective film 90 was subjected to heat treatment by being heated at 200° C. for 10 minutes in the air atmosphere. After the substrate with a multilayer reflective film 90 was subjected to the heat treatment, a reflectance (R2, unit: %) of the substrate with a multilayer reflective film 90 with respect to EUV light was measured. By subtracting a value of the reflectance (R2) of the substrate with a multilayer reflective film 90 after the heat treatment from a value of the reflectance (R1) of the substrate with a multilayer reflective film 90 before the heat treatment, a change in EUV reflectance of the substrate with a multilayer reflective film 90 due to the heat treatment was obtained. Table 1 presents a change in EUV reflectance due to the heat treatment.

As presented in Table 1, in the substrates with a multilayer reflective film 90 of Examples 1 to 8, the reflectance with respect to EUV light changed by 1.1% (Example 4) or less after the heat treatment at 200° C. for 10 minutes as compared with that before the heat treatment. Since each of the multilayer reflective films 2 of Examples 1 to 8 includes the predetermined intermediate layer 26, diffusion of Si from the high refractive index layer 22 to the low refractive index layer 24 was suppressed. Therefore, it is presumed that the reflectance slightly changed after the heat treatment as compared with that before the heat treatment. In particular, the change in reflectance of each of Examples 2, 3, and 7 in which the material of the intermediate layer 26 was SiN was as small as 0.1%.

Meanwhile, in the substrate with a multilayer reflective film 90 of Comparative Example 1, the reflectance of the substrate with a multilayer reflective film 90 with respect to EUV light more largely changed after the heat treatment at 200° C. for 10 minutes as compared with that before the heat treatment than those in Examples 1 to 8. In Comparative Example 1, it is presumed that Si was diffused from the high refractive index layer 22 to the low refractive index layer 24, a metal silicide (RuSi) was formed in the high refractive index layer 22, and the reflectance thereby largely changed.

### (Reflective Mask Blank 100)

Next, reflective mask blanks 100 of Examples 1 to 8 will be described.

By forming the conductive back film 5 on a back surface of the substrate 1 of the substrate with a multilayer reflective film 90 manufactured as described above, and forming the absorber film 4 on the protective film 3, the reflective mask blanks 100 of Examples 1 to 8 were manufactured.

First, the conductive back film 5 constituted by a CrN film was formed on the second main surface (back surface) of the substrate 1 of the substrate with a multilayer reflective film 90 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

Next, a TaBN film having a film thickness of 55 nm was formed as the absorber film 4 on the protective film 3 of the substrate with a multilayer reflective film 90. A composition of the absorber film 4 was Ta:B:N=75:12:13 (atomic ratio), and the absorber film 4 had a film thickness of 55 nm.

As described above, the reflective mask blanks 100 of Examples 1 to 8 were manufactured.

### (Reflective Mask 200)

Next, the reflective mask 200 was manufactured using each of the reflective mask blanks 100 of Examples 1 to 8. The manufacture of the reflective mask 200 will be described with reference to FIGS. 6A to 6D.

First, as illustrated in FIG. 6A, the resist film 11 was formed on the absorber film 4 of the reflective mask blank 100. Then, a desired pattern such as a circuit pattern was drawn (exposed) on the resist film 11 and further developed and rinsed to form the predetermined resist pattern 11a. (FIG. 6B). Next, using the resist pattern 11a as a mask, the absorber film 4 (TaBN film) was dry-etched using Cl₂ gas to form the absorber pattern 4a (FIG. 6C). Next, the resist pattern 11a was removed (FIG. 6D).

Finally, wet cleaning was performed with deionized water (DIW) to manufacture each of the reflective masks 200 of Examples 1 to 8.

### (Manufacture of Semiconductor Device)

The reflective masks 200 of Examples 1 to 8 were each set in an EUV scanner, and EUV exposure was performed on a wafer on which a film to be processed and a resist film were formed on the semiconductor substrate 60 which is a transferred object. Then, this resist film that had been subjected to exposure was developed to form a resist pattern on the semiconductor substrate 60 on which the film to be processed was formed.

The reflective masks 200 of Examples 1 to 8 each include the multilayer reflective film 2 having a shallow effective reflective surface and capable of suppressing a phenomenon that atoms to be a material are diffused between the low refractive index layer and the high refractive index layer. Therefore, a fine and highly accurate transfer pattern (resist pattern) could be formed on the semiconductor substrate 60 (transferred substrate).

This resist pattern was transferred onto the film to be processed by etching, and through various steps such as formation of an insulating film and a conductive film, introduction of a dopant, and annealing, a semiconductor device having desired characteristics could be manufactured at a high yield.

TABLE 1

| | | | | Content of | | Change |
|---|---|---|---|---|---|---|
| | Film | | | additive | Material | in EUV |
| | thickness | | | element in | of Si- | reflectance |
| | of high | | Film | multilayer | containing | by heat |
| | refractive | Material of | thickness of | reflective | layer in | treatment |
| | index layer | intermediate | intermediate | film | protective | (R1-R2) |
| | (nm) | layer | layer (nm) | (atom %) | film | (%) |
| Example 1 | 3.9 | SiN | 0.3 | N = 18 | Si | 0.2 |
| Example 2 | 3.6 | SiN | 0.6 | N = 20 | Si | 0.1 |
| Example 3 | 3.9 | SiN | 0.3 | N = 34 | Si | 0.1 |
| Example 4 | 3.9 | SiC | 0.3 | C = 24 | Si | 1.1 |
| Example 5 | 3.3 | SiC | 0.9 | C = 26 | Si | 0.8 |
| Example 6 | 3.9 | SiC | 0.3 | C = 30 | Si | 0.9 |
| Example 7 | 3.9 | SiN | 0.3 | N = 18 | Si/SiN | 0.1 |
| Example 8 | 3.3 | SiC | 0.9 | C = 26 | Si/SiC | 0.6 |

### REFERENCE SIGNS LIST

1 Substrate
2 Multilayer reflective film
3 Protective film
4 Absorber film
4a Absorber pattern
5 Conductive back film
6 Etching mask film
11 Resist film
11a Resist pattern
22 High refractive index layer
24 Low refractive index layer
26 Intermediate layer
50 EUV exposure apparatus
51 EUV light generation unit
52 Laser light source
53 Tin droplet generation unit
54 Catching unit
55 Collector
56 Irradiation optical system
57 Projection optical system
58 Reticle stage
59 Wafer stage
60 Semiconductor substrate
90 Substrate with a multilayer reflective film
100 Reflective mask blank
200 Reflective mask

1. A substrate with a multilayer reflective film comprising a substrate and a multilayer reflective film formed above the substrate, wherein
the multilayer reflective film comprises a low refractive index layer and a high refractive index layer comprising silicon (Si) that are alternately layered,
the multilayer reflective film further comprises at least one intermediate layer disposed between the low refractive index layer and the high refractive index layer,
the intermediate layer comprises a same material as the high refractive index layer and at least one additive element selected from nitrogen (N), carbon (C), and oxygen (O), and
the content of the additive element in the multilayer reflective film is 40 atom % or less.

2. The substrate with a multilayer reflective film according to claim 1, wherein the content of the additive element is 1 atom % or more.

3. The substrate with a multilayer reflective film according to claim 1, wherein the intermediate layer comprises at least one selected from SiN, SiO, SiC, SiON, SiCN, SiOC, and SiOCN.

4. The substrate with a multilayer reflective film according to claim 1, wherein the low refractive index layer comprises ruthenium (Ru).

5. The substrate with a multilayer reflective film according to claim 1, wherein
the low refractive index layer comprises ruthenium (Ru),
a stack of the one low refractive index layer and the one high refractive index layer is taken as one period, and
the stack is layered for less than 40 periods.

6. The substrate with a multilayer reflective film according to claim 1, further comprising a protective film on the multilayer reflective film.

7. The substrate with a multilayer reflective film according to claim 6, wherein the protective film comprises a SiN material layer comprising silicon (Si) and nitrogen (N) or a SiC material layer comprising silicon (Si) and carbon (C) on a side in contact with the multilayer reflective film.

8. (canceled)

9. A reflective mask blank comprising:
a substrate;
a multilayer reflective film above the substrate; and
an absorber film above the multilayer reflective film, wherein
the multilayer reflective film comprises a low refractive index layer and a high refractive index layer comprising silicon (Si) that are alternately layered,
the multilayer reflective film further comprises at least one intermediate layer disposed between the low refractive index layer and the high refractive index layer,
the intermediate layer comprises a same material as the high refractive index layer and at least one additive element selected from nitrogen (N), carbon (C), and oxygen (O), and
the content of the additive element in the multilayer reflective film is 40 atom % or less.

10. A reflective mask comprising:
a substrate;
a multilayer reflective film above the substrate; and
an absorber pattern obtained above the multilayer reflective film, wherein
the multilayer reflective film comprises a low refractive index layer and a high refractive index layer comprising silicon (Si) that are alternately layered,
the multilayer reflective film further comprises at least one intermediate layer disposed between the low refractive index layer and the high refractive index layer,
the intermediate layer comprises a same material as the high refractive index layer and at least one additive element selected from nitrogen (N), carbon (C), and oxygen (O), and
the content of the additive element in the multilayer reflective film is 40 atom % or less.

11. (canceled)

12. The reflective mask blank according to claim 9, wherein the content of the additive element is 1 atom % or more.

13. The reflective mask blank according to claim 9, wherein the intermediate layer comprises at least one selected from SiN, SiO, SiC, SiON, SiCN, SiOC, and SiOCN.

14. The reflective mask blank according to claim 9, wherein the low refractive index layer comprises ruthenium (Ru).

15. The reflective mask blank according to claim 9, wherein
the low refractive index layer comprises ruthenium (Ru),
a stack of the one low refractive index layer and the one high refractive index layer is taken as one period, and
the stack is layered for less than 40 periods.

16. The reflective mask blank according to claim 9, wherein the additive element comprises nitrogen (N) and wherein a content of nitrogen is between 5 and 20 atom %.

17. The reflective mask blank according to claim 9, wherein the additive element comprises carbon (C) and wherein a content of carbon is between 10 and 30 atom %.

18. The reflective mask blank according to claim 9, wherein the additive element comprises oxygen (O) and wherein a content of carbon is between 3 and 15 atom %.

19. The reflective mask according to claim 10, wherein the content of the additive element is 1 atom % or more.

20. The reflective mask according to claim 10, wherein the intermediate layer comprises at least one selected from SiN, SiO, SiC, SiON, SiCN, SiOC, and SiOCN.

21. The reflective mask according to claim 10, wherein the low refractive index layer comprises ruthenium (Ru).

22. The reflective mask according to claim 10, wherein
the low refractive index layer comprises ruthenium (Ru),
a stack of the one low refractive index layer and the one high refractive index layer is taken as one period, and
the stack is layered for less than 40 periods.

23. The reflective mask according to claim 10, wherein the additive element comprises nitrogen (N) and wherein a content of nitrogen is between 5 and 20 atom %.

24. The reflective mask according to claim 10, wherein the additive element comprises carbon (C) and wherein a content of carbon is between 10 and 30 atom %.

25. The reflective mask according to claim 10, wherein the additive element comprises oxygen (O) and wherein a content of oxygen is between 3 and 15 atom %.
